(19) United States
(12) Patent Application Publication
(10) Pub. No.: US 2021/0090231 A1
(43) Pub. Date: Mar. 25, 2021

(54) METHOD AND APPARATUS OF DETERMINING MARK POSITION

(71) Applicant: CANON KABUSHIKI KAISHA, Tokyo (JP)

(72) Inventor: Shinichi Egashira, Utsunomiya-shi (JP)

(21) Appl. No.: 17/021,520

(22) Filed: Sep. 15, 2020

(30) Foreign Application Priority Data
Sep. 19, 2019 (JP) 2019-170807

(51) Int. Cl. G06T 7/00; G03F 7/00; G06T 7/70

(52) U.S. Cl. CPC G06T 7/001; G03F 7/0002; G06T 2207/30148; G06T 2207/10056; G06T 7/70

(57) ABSTRACT

A method of determining a mark position, includes determining, based on a position of a mark image on an image acquired by using a scope that captures an image of a mark, a temporary position of the mark image, determining a correction amount for correcting the temporary position based on a distortion map indicating a two-dimensional distribution of distortion amounts of the scope, and the mark image, and determining a position of the mark by correcting the temporary position based on the correction amount.

### BACKGROUND OF THE INVENTION

### Field of the Invention

The present invention relates to a method of determining a mark position, a lithography method, a method of manufacturing an article, a memory medium, and a lithography apparatus.

### Description of the Related Art

The position of a mark provided on a substrate or the like can be detected by capturing an image of the mark using a scope and processing the obtained image. If the scope has non-negligible distortion, the distortion can influence the detection accuracy of the position of a mark. Japanese Patent Laid-Open No. 2005-285916 discloses a method of measuring the position of a target, feeding the target to the visual field center of an optical system, and then again measuring the position of the target. Japanese Patent Laid-Open No. 2006-30021 discloses a method of correcting a measured value by acquiring in advance the influence of distortion on a region where a target is observed.

The method disclosed in Japanese Patent Laid-Open No. 2005-285916 requires the processing of placing a target to the visual field center, thus prolonging the time required for measurement. The method disclosed in Japanese Patent Laid-Open No. 2006-30021 cannot implement accurate correction because the amount of influence of distortion changes in accordance with the shape of a mark.

### SUMMARY OF THE INVENTION

The present invention provides a technique advantageous in detecting the position of a mark with high accuracy.

A first aspect of the present invention provides a method of determining a mark position, comprising: determining, based on a position of a mark image on an image acquired by using a scope that captures an image of a mark, a temporary position of the mark image; determining a correction amount for correcting the temporary position based on a distortion map indicating a two-dimensional distribution of distortion amounts of the scope, and the mark image; and determining a position of the mark by correcting the temporary position based on the correction amount.

A second aspect of the present invention provides a lithography method of transferring a pattern onto a substrate, the method comprising: detecting a position of a mark provided on the substrate in accordance with the mark position determination method as defined as the first aspect; and transferring a pattern to a target position on the substrate based on the position of the mark detected in the detecting.

A third aspect of the present invention provides a method of manufacturing an article, the method comprising: transferring a pattern onto a substrate by the lithography method as defined as the second aspect; processing the substrate having undergone the transferring; and obtaining the article from the substrate having undergone the processing.

A fourth aspect of the present invention provides a non-transitory computer-readable medium storing a program causing a computer to execute the mark position determination method as defined as the first aspect.

A fifth aspect of the present invention provides a lithography apparatus comprising a scope configured to capture an image of a mark provided on a substrate and a processor configured to detect a position of the mark based on an image captured by the scope, and configured to transfer a pattern to a target position on the substrate based on the position of the mark detected by the processor, the processor is configured to: determine, based on a position of a mark image on an image acquired by using the scope configured to capture an image of the mark, a temporary position of the mark image, determine a correction amount for correcting the temporary position based on a distortion map indicating a two-dimensional distribution of distortion amounts of the scope and the mark image, and determine the position of the mark by correcting the temporary position based on the correction amount.

Further features of the present invention will become apparent from the following description of exemplary embodiments with reference to the attached drawings.

### BRIEF DESCRIPTION OF THE DRAWINGS

FIG. 1 is a view schematically showing the arrangement of a lithography apparatus according to an embodiment of the present invention;

FIG. 2 is a view showing an example of the arrangement of an alignment scope;

FIG. 3 is a view exemplarily showing a mark for pre-alignment;

FIG. 4 is a view exemplarily showing a mark for fine alignment;

FIG. 5 is a flowchart showing the processing of exposing a substrate to light while performing alignment measurement in the first mode;

FIGS. 6A and 6B are flowcharts each showing a procedure for processing of exposing a substrate to light while performing alignment measurement in the second mode;

FIGS. 7A and 7B are views for explaining distortion;

FIG. 8 is a view exemplarily showing a region located at a peripheral portion of a visual field;

FIG. 9 is a view exemplarily showing a distortion map;

FIG. 10 is a view showing the first example of a mark image;

FIG. 11 is a view showing the relationship between the first example of the mark image and distortion;

FIG. 12 is a view showing the amount of distortion influencing the detection of the position of the first example of the mark image in the X direction;

FIG. 13 is a view showing the amount of distortion influencing the detection of the position of the first example of the mark image in the Y direction;

FIG. 14 is a view showing the second example of a mark image;

FIG. 15 is a view showing the relationship between the second example of the mark image and distortion;

FIG. 16 is a view schematically showing a method of generating a distortion map according to the first modification;

FIG. 17 is a view schematically showing a method of generating a distortion map according to the second modification;

FIG. 18 is a view for explaining another example of a method of determining a correction amount; and

FIG. 19 is a view for explaining still another example of a method of determining a correction amount.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

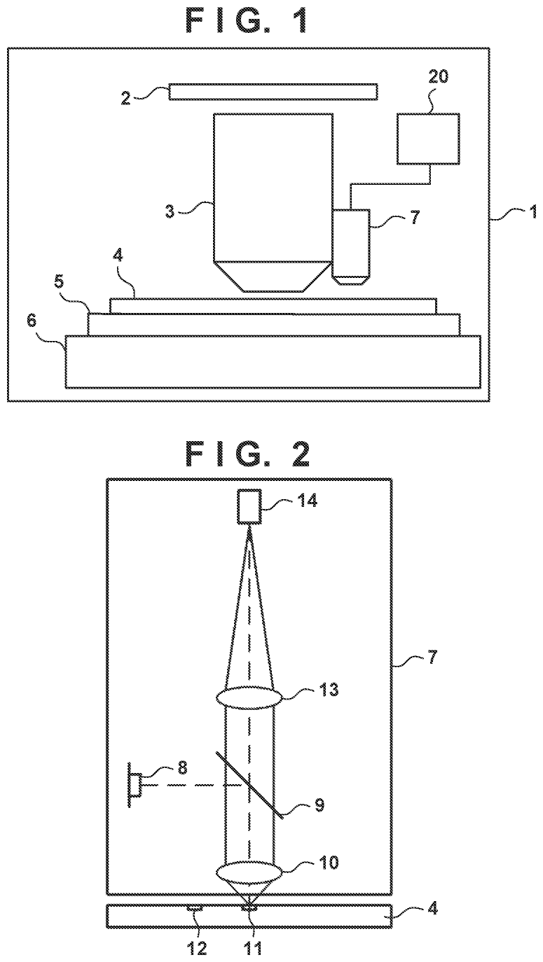

FIG. 1 schematically shows the arrangement of a lithography apparatus 1 according to an embodiment of the present invention. The lithography apparatus 1 can be configured as a transfer apparatus that transfers a pattern onto a substrate 4. In this embodiment, the lithography apparatus 1 is configured as an exposure apparatus that transfers the pattern of an original plate 2 onto the substrate 4 (its photoresist film), but may be configured as an apparatus that transfers the pattern of an original plate (mold) onto an imprint material on the substrate 4.

The lithography apparatus 1 can include a projection optical system 3, a substrate chuck 5, a substrate driving mechanism 6, an alignment scope (scope) 7, and a control unit (processor) 20. The projection optical system 3 projects the pattern of the original plate 2 illuminated with light by an illumination optical system (not shown) onto the substrate 4. The substrate chuck 5 holds the substrate 4. The substrate 4 can have, for example, an underlying pattern and marks (alignment marks) 11 and 12 formed in the preceding step and a photoresist film arranged to cover them. The mark 11 can be a pre-alignment mark. The mark 12 can be a fine alignment mark.

The substrate driving mechanism 6 drives the substrate 4 by driving the substrate chuck 5. The alignment scope 7 includes a microscope and an image sensing device and captures an image of a mark provided on the substrate 4. The control unit 20 can detect the position of the mark on the substrate 4 based on the image captured by the alignment scope 7. In addition, the control unit 20 controls, for example, an operation pertaining to the transfer of the pattern of the original plate 2 onto the substrate 4. The control unit 20 can be implemented by, for example, a PLD (the abbreviation of a Programmable Logic Device) such as an FPGA (the abbreviation of a Field Programmable Gate Array), an ASIC (the abbreviation of an Application Specific Integrated Circuit), a general-purpose or dedicated computer incorporating programs, or a combination of all or some of them. The present invention can also be implemented by a program for causing the computer to execute the method described in this specification (for example, the mark position detection method) and a memory medium (computer-readable memory medium) storing the program.

FIG. 2 shows an example of the arrangement of the alignment scope 7. The alignment scope 7 can include, for example, a light source 8, a beam splitter 9, optical systems 10 and 13, and an image sensing device 14. The illumination light emitted from the light source 8 is reflected by the beam splitter 9 and illuminates the mark 11 (12) on the substrate 4 through the optical system 10. The diffracted light from the mark 11 enters the image sensing device 14 through the optical system 10, the beam splitter 9, and the optical system 13 to form an optical image of the mark 11 (12) on the image capturing surface of the image sensing device 14. The image sensing device 14 captures the optical image and outputs an image (image data) including a mark image (mark image data) as an image (image data) of the mark 11. The light source 8, the beam splitter 9, the optical systems 10 and 13, and the mark 11 (12) constitute a microscope for observation.

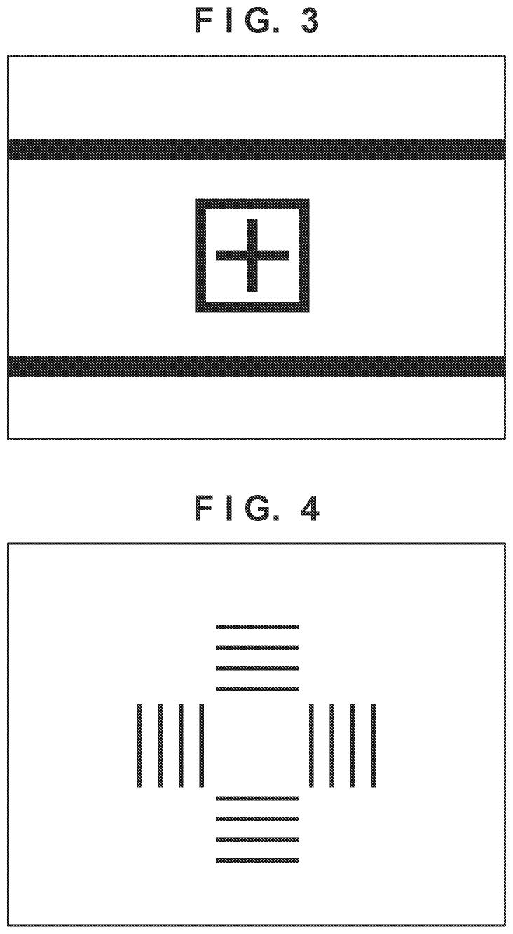

The microscope can have a magnification that enables both pre-alignment measurement capable of searching for a mark over a wide range and fine alignment measurement capable of accurately performing measurement. Conventionally, an arrangement using different optical systems for pre-alignment measurement and fine alignment measurement has been widely used, and hence alignment marks having different shapes depending on such applications have been used. FIG. 3 exemplarily shows the mark 11 for pre-alignment. FIG. 4 exemplarily shows the mark 12 for fine alignment. The marks 11 and 12 having shapes optimized according to a process for a wafer are often used. Accordingly, marks having various shapes are available.

The lithography apparatus 1 can have the first and second modes concerning alignment measurement. The processing of exposing a substrate to light while performing alignment measurement in the first mode will be described first. The processing of exposing the substrate to light while performing alignment measurement in the second mode will be described afterward.

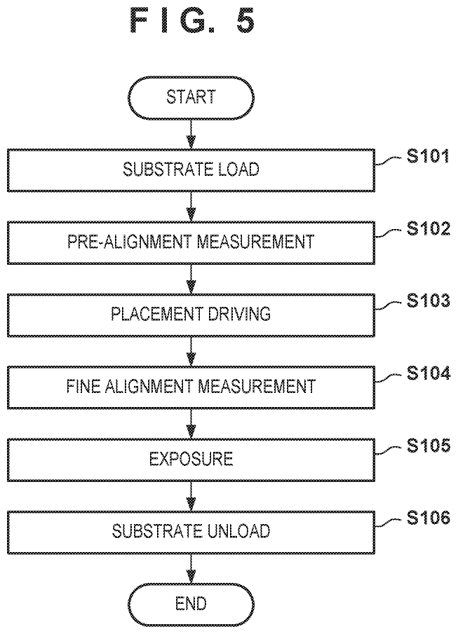

FIG. 5 shows a procedure for the processing of exposing a substrate to light while performing alignment measurement in the first mode. The control unit 20 controls this processing. In step S101, the control unit 20 loads the substrate 4 into the lithography apparatus 1 and causes the substrate chuck 5 to hold the substrate 4. In step S102, the control unit 20 performs pre-alignment measurement. More specifically, in pre-alignment measurement, the control unit 20 detects the position of the mark 11 for pre-alignment by using the alignment scope 7, and roughly calculates the position of the substrate 4 based on the detection result. In this case, the position of the mark 11 is detected concerning a plurality of shot regions on the substrate 4. This makes it possible to calculate the overall shift and linear components (magnification and rotation) of the substrate 4.

In step S103, the control unit 20 performs placement driving based on the pre-alignment measurement result. In placement driving, the control unit 20 causes the substrate driving mechanism 6 to drive the substrate 4 based on the pre-alignment measurement result so as to cause the mark 12 for fine alignment to fall within the central portion of the visual field of the alignment scope 7. In step S104, the control unit 20 performs fine alignment measurement. More specifically, in fine alignment measurement, the control unit 20 detects the position of the mark 12 for pre-alignment by using the alignment scope 7, and detects the position of the substrate 4. It is possible to precisely calculate the overall shift and linear components (magnification and rotation) of the substrate 4 based on the detection result. In this case, repeating steps S103 and S104 detects the position of the mark 12 concerning a plurality of shot regions (a plurality of sample shot regions) on the substrate 4. The high-order deformation components of the substrate 4 may be precisely calculated by increasing the number of marks 12 for the detection of a position.

In step S105, the control unit 20 aligns each shot region on the substrate 4 with the original plate 2 based on the fine alignment measurement result, and exposes each shot region to light. Subsequently, in step S106, the control unit 20 unloads the substrate 4.

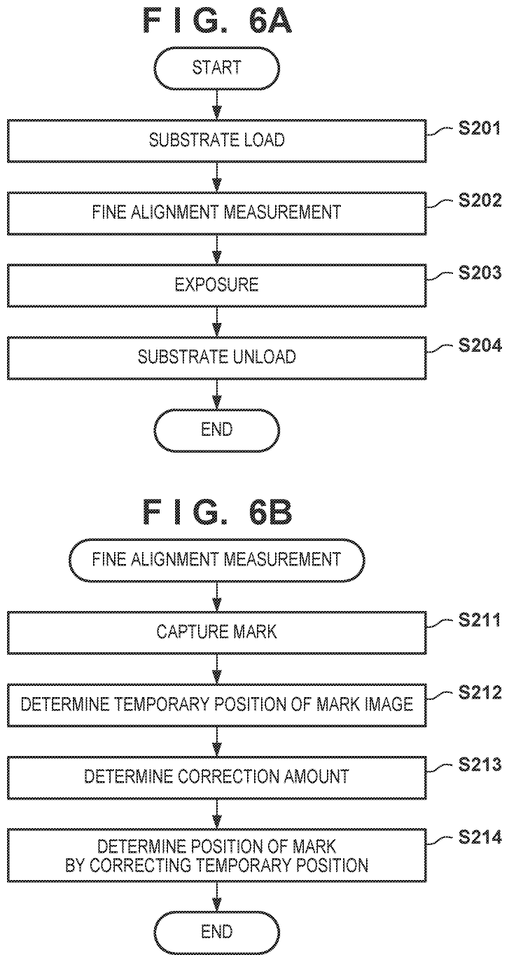

FIGS. 6A and 6B each show a procedure for the processing of exposing a substrate to light while performing alignment measurement in the second mode. The control unit 20 controls this processing. Pre-alignment measurement is not performed in the second mode. FIG. 6A shows an outline of an operation in the second mode. FIG. 6B shows the details of step S202 (fine alignment measurement).

In step S201, the control unit 20 loads the substrate 4 into the lithography apparatus 1 and causes the substrate chuck 5 to hold the substrate. In step S202, the control unit 20 performs fine alignment measurement. In fine alignment measurement, the control unit 20 detects the position of the mark 12 for fine alignment by using the alignment scope 7. The control unit 20 detects the position of the mark 12 with regard to a plurality of shot regions (a plurality of sample shot regions) on the substrate 4. In the second mode, pre-alignment measurement and placement driving are not performed, and hence the mark 12 is not necessarily located in the central portion of the visual field of the alignment scope 7. That is, the mark 12 may be placed in a peripheral portion of the visual field of the alignment scope 7. Accordingly, the position of an image of the mark 12 (mark image) observed (captured) with the alignment scope 7 (microscope) is influenced by distortion. Therefore, the control unit 20 executes processing (FIG. 6B) for correcting this influence.

In step S203, the control unit 20 aligns each shot region on the substrate 4 with the original plate 2 based on the fine alignment measurement result and exposes each shot region to light. Subsequently, in step S204, the control unit 20 unloads the substrate 4.

A mark position determination method applied to step S202 (fine alignment measurement) in FIG. 6A will be described below with reference to FIG. 6B. In step S211, the control unit 20 captures an image of the mark 12 for pre-alignment by using the alignment scope 7. With this step, an image (image data) including a mark image (mark image data) that is an image (image data) of the mark 12 is acquired. In step S212 (first step), the control unit 20 determines, as a temporary position, the position of the mark image on the image acquired in step S211. There is a possibility that this temporary position is an inaccurate position (a position including an error) influenced by the distortion of the alignment scope 7 (microscope).

In step S213 (second step), the control unit 20 determines a correction amount for correcting the temporary position determined in step S212 based on a distortion map (to be described later) indicating the two-dimensional distribution of distortion amounts of the alignment scope 7 and the mark image acquired in step S211. In step S214 (third step), the control unit 20 determines the position of the mark 12 by correcting the temporary position determined in step S212 based on the correction amount determined in step S213. Note that the processing shown in FIG. 6B may be applied to fine alignment measurement in the first mode.

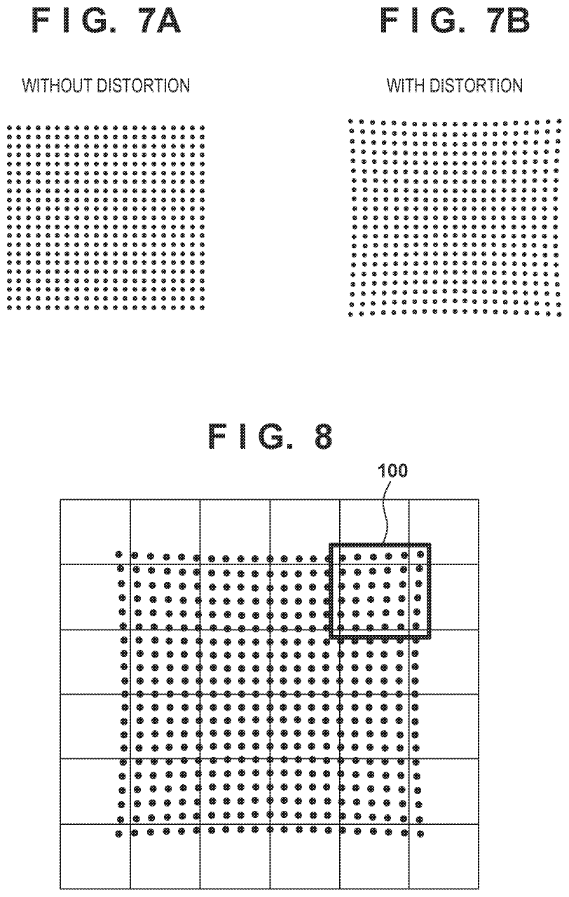

The processing shown in FIG. 6B will be described below with reference to a specific example. FIGS. 7A and 7B each show the image obtained by capturing an image of a dot chart having dots respectively arranged at lattice elements of a square lattice by using the alignment scope 7. FIG. 7A shows the image when the alignment scope 7 has no distortion. FIG. 7B shows the image when the alignment scope 7 has distortion. When the alignment scope 7 has no distortion, the dot chart is arranged to form a true square lattice. When the alignment scope 7 has distortion, the dot chart distorts at a peripheral portion of the visual field of the alignment scope 7. For this reason, when the image of the mark 12 is located at the peripheral portion of the visual field of the alignment scope 7, a position different from the position where the mark 12 is actually present is detected as the temporary position of the mark image corresponding to the mark 12 in step S212.

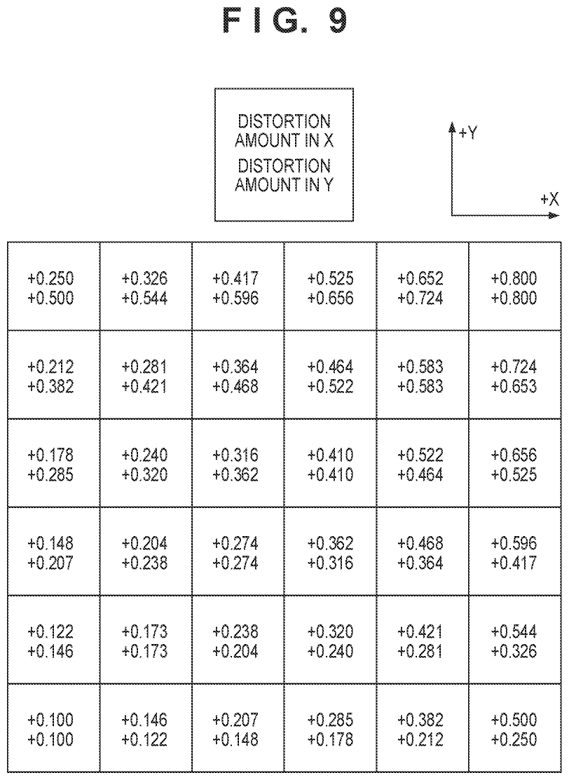

Specifically described next is how distortion occurs at the detection position of the mark 12 when the alignment scope 7 has distortion. FIG. 8 shows the visual field of the alignment scope 7. The following will exemplify a region 100 located at a peripheral portion of the visual field shown in FIG. 8. FIG. 9 exemplarily shows a distortion map pertaining to the region 100. The distortion map indicates the two-dimensional distribution of the distortion amounts of the alignment scope 7 (shift amounts from ideal positions (positions without any distortion)). In other words, the distortion map is obtained by arranging the distortion amounts of the alignment scope 7 at the respective lattice elements constituting the lattice.

Referring to FIG. 9, two numerical values are written in each lattice element. The numerical value on the upper side represents a distortion amount in the X direction (first distortion amount), and the numerical value on the lower side represents a distortion amount in the Y direction (second distortion amount).

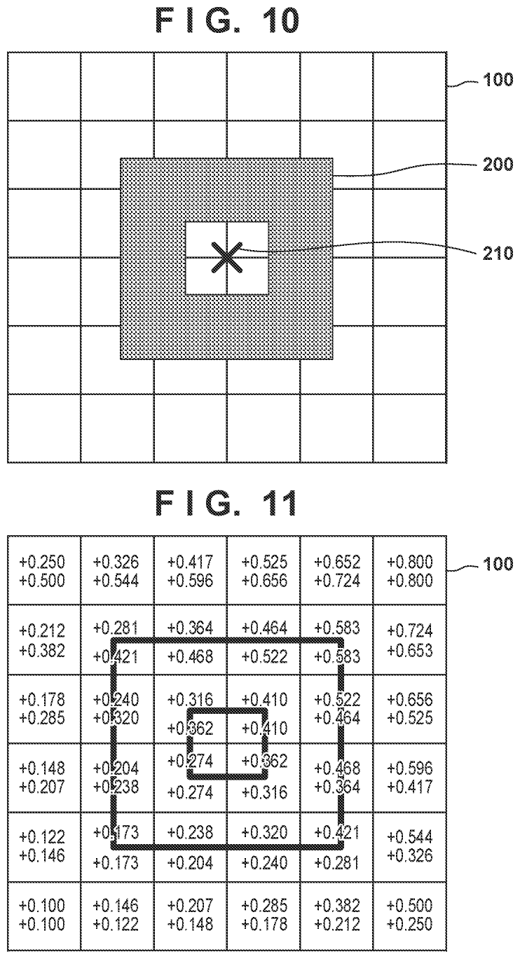

In this case, the unit for providing a practical example is set as μm, but is merely an example. For example, the rightmost/uppermost lattice element indicates that the distortion amount (the shift amount from the ideal position) is X=+0.800 μm and Y=+0.800 μm. When the distortion shown in FIG. 9 has occurred, the position of a mark image 200 shown in FIG. 10 is detected as a center position 210 of the region 100. However, the position at which the mark on the substrate actually exists and which corresponds to the mark image 200 is shifted from the center position 210 by a shift amount corresponding to the influence of the distortion amount in the lattice element.

The position of the mark image is calculated from the information of the edges of the mark image. The shift amount of the mark image due to the influences of the distortion amounts in the X and Y directions can be obtained by statistically processing the distortion amounts in a plurality of lattice elements on the distortion map, which distortion amounts correspond to the edges of the mark image shown in FIG. 11. The statistic processing can be, for example, the processing of obtaining an average value (for example, an arithmetic mean value). In this case, the mark image can have a first edge crossing the X direction (the first direction) (an edge extending in the Y direction) and a second edge crossing the Y direction (the second direction) orthogonal to the X direction (an edge extending in the X direction).

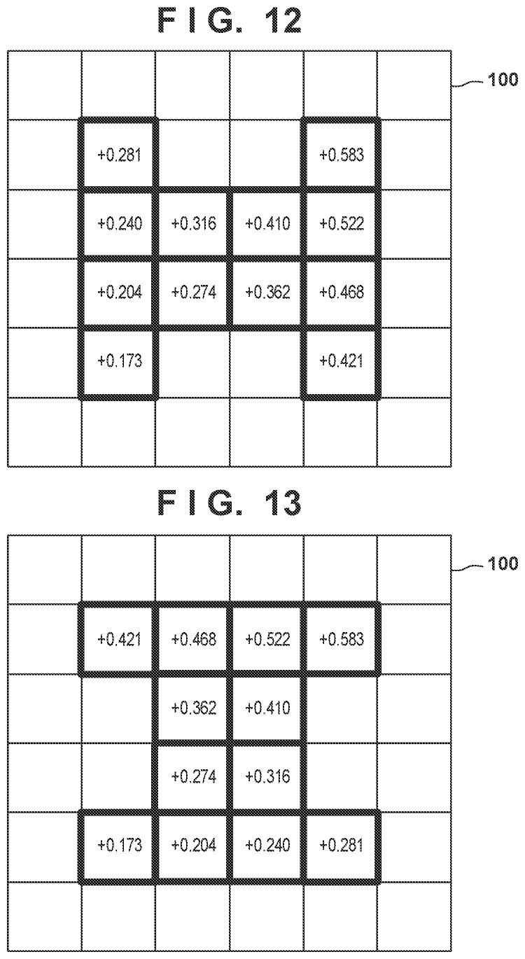

FIG. 12 shows lattice elements for calculating the shift amount (first correction amount) of the mark image due to the distortion amount in the X direction. These lattice elements are obtained by extracting lattice elements including the first edge crossing the X direction (first direction) (the edge extending in the Y direction) from FIG. 11. In step S213, based on this, the shift amount in the X direction as a correction amount for correcting the temporary position of the mark image in the X direction can be calculated as follows:

X=(0.281+0.240+0.204+0.173+0.316+0.274+0.410+0.362+0.583+0.522+0.468+0.421)/12

FIG. 13 shows lattice elements for calculating the shift amount (second correction amount) of the mark image due to the distortion amount in the Y direction. These lattice elements are obtained by extracting lattice elements including the second edge crossing the Y direction (second direction) (the edge extending in the X direction) from FIG. 11. In step S213, based on this, the shift amount in the Y direction as a correction amount for correcting the temporary position of the mark image in the Y direction can be calculated as follows:

Y=(0.421+0.468+0.522+0.583+0.362+0.410+0.274+0.316+0.173+0.204+0.240+0.281)/12

In the above example, both a correction amount Δx in the X direction and a correction amount Δy in the Y direction are +0.355 μm. That is, when the alignment scope 7 has the distortion shown in FIG. 7B, the position of the mark image captured as shown in FIG. 10 in the region 100 has measurement shifts of +0.355 μm in the X and Y directions with respect to the actual position of the corresponding mark on the substrate 4. In step S213, the temporary position of the mark image determined in step S211 is corrected based on the correction amounts (in the above case, Δx =+0.355 μm and Δy=+0.355 μm) determined in step S212. More specifically, letting (x′, y′) be the temporary position, (x, y) be the corrected position of the mark, and (Δx, Δy) be the correction amount, the position of the mark can be calculated according to the following equation.

(x, y)=(x′, y′)−(Δx, Δy)

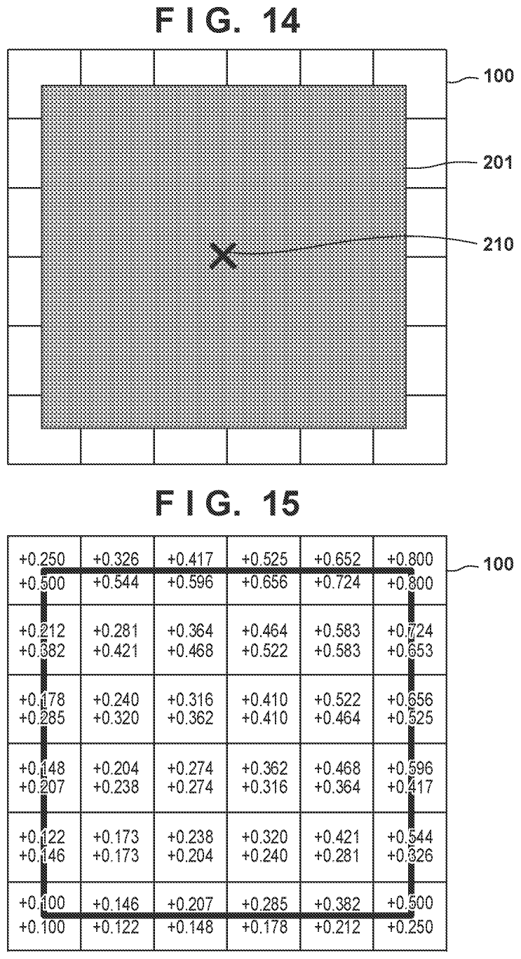

The detection of a mark having another shape will be described below. When a mark image 201 shown in FIG. 14 is captured by using the alignment scope 7, the position of the mark image 201 is the center position 210 of the region 100, which is detected as the temporary position of the mark image 201.

In this case as well, the shift amount of the mark image 201, that is, the correction amount, can be calculated as the average value (for example, the arithmetic mean value) of distortion amounts in the lattice elements where the edges of the mark image exist, as shown in FIG. 15. In this case, the correction amount is given as (Δx, Δy)=(+0.403 μm, +0.403 μm).

The example in FIG. 10 differs in shift amount (correction amount) from the example in FIG. 14. This indicates that even if the center positions of mark images are at the same position in the visual field of the alignment scope 7, the corresponding shift amounts (correction amounts) differ according to the shapes of the mark images (marks). That is, when the influence of this distortion is to be removed, it is necessary to determine a correction amount according to the shape of a mark. In this embodiment, in step S213, a correction amount for correcting the temporary position determined in step S212 is determined based on the distortion map and the mark image acquired in step S211.

A distortion map can be generated by dividing the visual field of the alignment scope 7 into a plurality of lattice elements and determining distortion amounts of the respective lattice elements. The distortion amounts of the respective lattice elements can be generated by, for example, capturing an image of the dot chart shown in FIGS. 7A and 7B with the entire region of the visual field of the alignment scope 7 and associating the shift amounts of the positions of the captured respective dots with the respective lattice elements. At this time, in order to minimize the influence of the measurement reproducibility of each dot, the shift amount of each dot can be obtained a plurality of times, and the obtained shift amounts can be averaged. The occurrence amount of distortion varies depending on the wavelength of alignment light at the time of observation of an alignment mark and illumination conditions. Accordingly, the occurrence amount can be accurately corrected by acquiring a distortion map for each condition and selectively using the acquired distortion maps. The lithography apparatus 1 can execute the step of generating a distortion map at the time of initialization when maintenance is performed periodically or arbitrarily. In this step, the control unit 20 can generate a distortion map based on the image obtained by capturing a dot chart having a plurality of dots arranged by using the alignment scope 7.

A method of determining a correction amount is not limited to the method described above with reference to step S213. In step S212, a method of determining a correction amount may be selected in accordance with a computation method for determining the position of a mark image in step S212. For example, there is available a method of determining the position of a mark image by extracting the edge portions of the mark image by differentiating the mark image and calculating the center of gravity of the strength information of the edge portions. When the temporary position of a mark image is determined by such a method, a correction amount can be obtained by calculating a weighted average value according to the differential value in each lattice element. A specific example of this method will be described below.

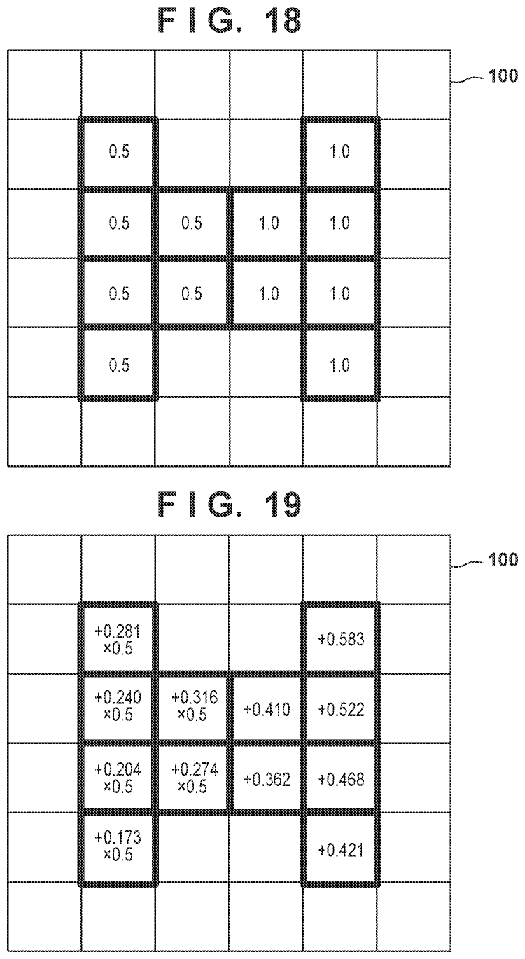

FIG. 18 exemplarily shows the values (to be referred to as the normalized differential values) obtained by normalizing the differential values of edges of a mark image which cross the X direction with 1.0. As exemplarily shown in FIG. 18, when the normalized differential values on the left side of a mark image differ from those on the right side, the distortion amounts in the respective lattice elements are weighted by normalized differential values, and a weighted average value is calculated, as exemplarily shown in FIG. 19. The calculated value can be a correction amount.

According to this embodiment, the position of a mark influenced by the distortion of the alignment scope 7 can be detected with high accuracy. This technique is useful especially when executing no pre-alignment measurement as in the second mode, that is, when executing fine alignment measurement in a situation in which a mark can exist in a peripheral portion of the visual field of the alignment scope 7. Note, however, that the correction of a temporary position in this embodiment can also be applied to the first mode. In this case as well, the position of a mark can be detected with high accuracy.

A modification of the step of generating a distortion map will be described below. In the first modification, the control unit 20 controls the processing of generating a distortion map so as to generate a distortion map based on the image captured by using the alignment scope 7 upon sequentially arranging dot marks at a plurality of positions in the visual field of the alignment scope 7.

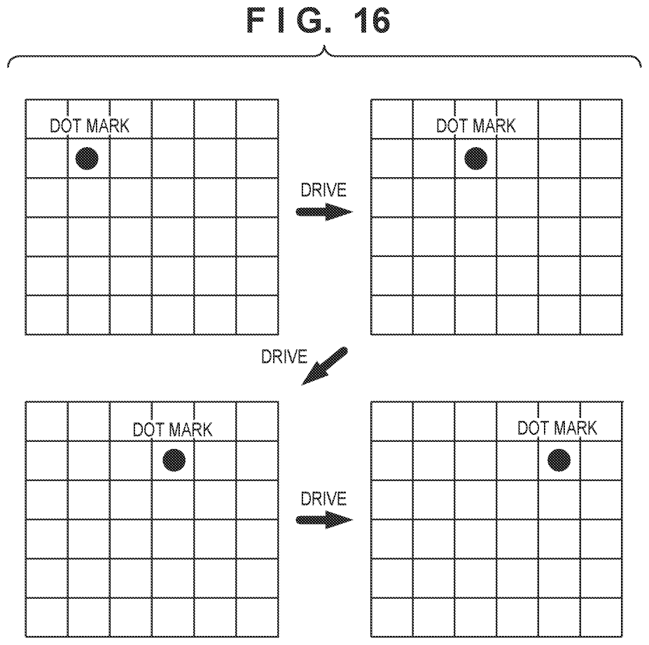

FIG. 16 schematically shows a method of generating a distortion map according to the first modification. First of all, a substrate having dot marks is arranged on the substrate chuck 5. Subsequently, the substrate driving mechanism 6 is operated to arrange a dot mark at an observation visual field position corresponding to one lattice element of a distortion map. The alignment scope 7 captures an image of the dot mark. The position of the dot mark image obtained in this manner is detected. The position of the dot mark on the substrate at this time is guaranteed by the positioning accuracy of the substrate driving mechanism 6, and the shift amount from the position of the dot mark image of the dot mark on the substrate is a distortion amount. Subsequently, similar processing is performed while the position of a lattice element at which a distortion amount is determined is sequentially changed. If the driving accuracy of the substrate driving mechanism 6 is high, because each dot mark can be moved to an almost ideal position, the shift amount between the position of a dot mark on the substrate and the position of the dot mark image can be a distortion amount. According to the first modification, a distortion map can be generated without using any dot chart having a plurality of dots arranged accurately.

In the second modification, the control unit 20 sequentially arranges an alignment mark at a plurality of positions within the visual field of the alignment scope 7, and generates a distortion map based on the images captured by using the alignment scope 7. In general, an alignment mark having an arbitrary shape is used. For this reason, alignment marks have various shapes including an alignment mark relatively frequently used such as a standard recommended alignment mark. In such a case, as the processing limited to such an alignment mark, it is possible to implement accurate correction by generating a distortion map using the alignment mark in the following sequence.

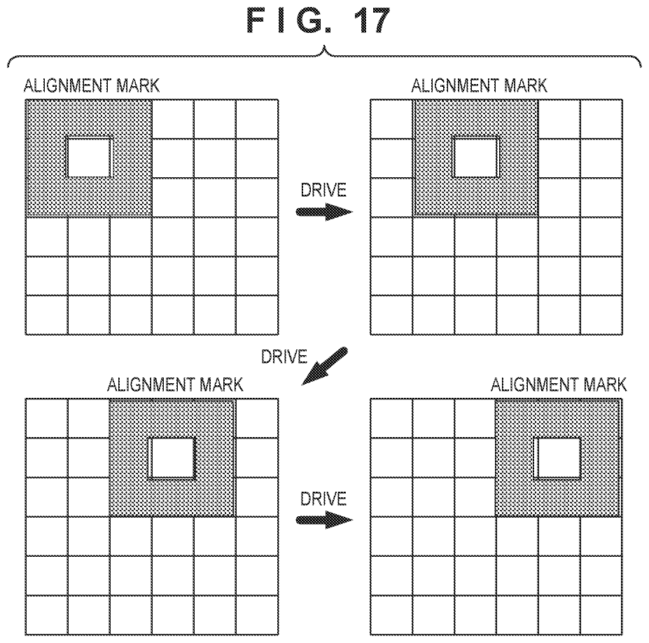

FIG. 17 schematically shows a method of generating a distortion map according to the second modification. First of all, a substrate having a selected alignment mark can be arranged on the substrate chuck 5. Subsequently, the substrate driving mechanism 6 is operated to arrange an alignment mark at an observation visual field position corresponding to one lattice element of the distortion map, and the alignment scope 7 captures an image of the alignment mark. The position of the alignment mark image obtained in the following manner is detected. The position of the alignment mark on the substrate at this time is guaranteed by the positioning accuracy of the substrate driving mechanism 6, and the shift amount between the position of the alignment mark on the substrate and the position of alignment is a distortion amount. Subsequently, similar processing is performed while the position of a lattice element at which a distortion amount is determined is sequentially changed.

According to the second modification, the distortion amount of each lattice element constituting a distortion map includes a detection error unique to the shape of the alignment mark used for the generation of the distortion map. Accordingly, when the shape of an alignment mark for alignment measurement is similar to the shape of an alignment mark for the generation of a distortion map, the distortion amount of the distortion map may be changed as a correction amount without any change. In this case, it may be determined in step S213 whether the shape of an alignment mark for alignment measurement is similar to the shape of an alignment mark for the generation of a distortion map. If the two shapes are similar to each other, the distortion amount of the distortion map may be used as a correction amount without any change. In contrast to this, if the two shapes are not similar to each other, a correction amount is determined in accordance with the embodiment described above. Alternatively, if it is more strictly determined that the two shapes do not coincide with each other, a correction amount can be determined in accordance with the embodiment described above.

Alternatively, a distortion map may be prepared for each of a plurality of types of alignment marks. In this case, it is possible to use, as a correction amount, the distortion amount of a distortion map generated by using an alignment mark similar to an alignment mark used in alignment.

Assume that when the position of a mark image is corrected, the center of the mark image is offset by an amount equal to or less than the size of a lattice element. In this case, a correction amount may be determined from the distortion amount of an adjacent lattice by interpolation (for example, linear interpolation).

According to this embodiment, the position of a mark can be accurately detected by correcting the position detection result on the mark image generated by the distortion of the alignment scope 7.

A lithography method executed by using the lithography apparatus 1 can include a detection step of detecting the position of a mark on the substrate 4 in accordance with the mark position determination method and a transfer step of transferring a pattern to a target position on the substrate 4 based on the position of the mark detected in the detection step.

A method of manufacturing an article according to one embodiment can include a transfer step of transferring a pattern onto the substrate 4 by the lithography method and a processing step of processing the substrate 4 having undergone the transfer step, and obtains an article from the substrate 4 having undergone the processing step. The processing can include, for example, development, etching, ion implantation, and deposition.

### Other Embodiments

Embodiment(s) of the present invention can also be realized by a computer of a system or apparatus that reads out and executes computer executable instructions (e.g., one or more programs) recorded on a storage medium (which may also be referred to more fully as anon-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-170807, filed Sep. 19, 2019, which is hereby incorporated by reference herein in its entirety.

What is claimed is:

1. A method of determining a mark position, comprising:
determining, based on a position of a mark image on an image acquired by using a scope that captures an image of a mark, a temporary position of the mark image;
determining a correction amount for correcting the temporary position based on a distortion map indicating a two-dimensional distribution of distortion amounts of the scope, and the mark image; and
determining a position of the mark by correcting the temporary position based on the correction amount.

2. The method according to claim 1, wherein in the determining the correction amount, the correction amount is determined based on the distortion amount in the distortion map, which corresponds to a position of an edge of the mark image.

3. The method according to claim 1, wherein the mark image has a first edge crossing a first direction and a second edge crossing a second direction orthogonal to the first direction,
the distortion amount includes a first distortion amount in the first direction and a second distortion amount in the second direction,
the correction amount includes a first correction amount concerning the first direction and a second correction amount concerning the second direction, and
in the determining the correction amount, the first correction amount is determined based on the first distortion amount in the distortion map, which corresponds to a position of the first edge, and the second correction amount is determined based on the second distortion amount in the distortion map, which corresponds to a position of the second edge.

4. The method according to claim 3, wherein in the determining the correction amount, the first correction amount is determined by performing statistical processing of a plurality of first distortion amounts corresponding to a plurality of positions of the first edge, and the second correction amount is determined by performing statistical processing of a plurality of second distortion amounts corresponding to a plurality of positions of the second edge.

5. The method according to claim 4, wherein the statistical processing includes processing of obtaining an average value.

6. The method according to claim 5, wherein the average value is an arithmetic mean value.

7. The method according to claim 5, wherein the average value is a weighted average value.

8. The method according to claim 1, further comprising generating the distortion map based on an image obtained by capturing an image of a dot chart having a plurality of dots arranged by using the scope.

9. The method according to claim 1, further comprising generating the distortion map based on an image captured by using the scope upon sequentially arranging a mark at a plurality of positions in a visual field of the scope.

10. The method according to claim 9, wherein the mark is a dot mark.

11. The method according to claim 9, wherein the mark is an alignment mark.

12. A lithography method of transferring a pattern onto a substrate, the method comprising:
detecting a position of a mark provided on the substrate in accordance with a mark position determination method defined in claim 1; and
transferring a pattern to a target position on the substrate based on the position of the mark detected in the detecting.

13. A method of manufacturing an article, the method comprising:
transferring a pattern onto a substrate by a lithography method defined in claim 12;
processing the substrate having undergone the transferring; and
obtaining the article from the substrate having undergone the processing.

14. A non-transitory computer-readable medium storing a program causing a computer to execute a mark position determination method defined in claim 1.

15. A lithography apparatus comprising a scope configured to capture an image of a mark provided on a substrate and a processor configured to detect a position of the mark based on an image captured by the scope, and configured to transfer a pattern to a target position on the substrate based on the position of the mark detected by the processor,
the processor is configured to:
determine, based on a position of a mark image on an image acquired by using the scope configured to capture an image of the mark, a temporary position of the mark image,
determine a correction amount for correcting the temporary position based on a distortion map indicating a two-dimensional distribution of distortion amounts of the scope and the mark image, and
determine the position of the mark by correcting the temporary position based on the correction amount.
